(19) United States
(12) Patent Application Publication
(10) Pub. No.: US 2014/0207398 A1
(43) Pub. Date: Jul. 24, 2014

(54) Transient Normalization for Appliance Classification, Disaggregation, and Power Estimation in Non-Intrusive Load Monitoring

(71) Applicant: Samsung Electronics Co., LTD, Suwon-si (KR)

(72) Inventors: Sean D. Lai, Richardson, TX (US); Suman Giri, Pittsburg, PA (US)

(73) Assignee: Samsung Electronics Co., LTD, Suwon-si (KR)

(21) Appl. No.: 14/097,011

(22) Filed: Dec. 4, 2013

Related U.S. Application Data
(60) Provisional application No. 61/755,816, filed on Jan. 23, 2013.
(60) Provisional application No. 61/755,827, filed on Jan. 23, 2013.

(51) Int. Cl. G01R 21/133

(52) U.S. Cl. CPC G01R 21/133
USPC 702/61

(57) ABSTRACT

Various apparatuses and methods are provided for monitoring individual appliance energy consumption using non-intrusive load monitoring (NILM). For example, one method includes detecting an ON event and an OFF event within a segment of streaming power input and extracting the streaming power input associated with the ON event in response to detecting the ON event. The extracted streaming power input includes a waveform associated with the ON event recorded over a time frame. The method also includes normalizing the waveform to reveal one or more unique variations and classifying the normalized waveform based on the one or more unique variations. The method further includes matching the ON event with a correlating OFF event based at least on the classification of the normalized waveform and calculating power consumed from a time of the ON event to a time of the OFF event.

### CROSS-REFERENCE TO RELATED APPLICATIONS AND PRIORITY CLAIM

This application claims priority under 35 U.S.C. §119(e) to:

U.S. Provisional Patent Application Ser. No. 61/755,816 filed on Jan. 23, 2013 and entitled “TRANSIENT NORMALIZATION FOR APPLIANCE CLASSIFICATION, DISAGGREGATION, AND POWER ESTIMATION IN NILM”; and

U.S. Provisional Patent Application Ser. No. 61/755,827 filed on Jan. 23, 2013 and entitled “OFF TRANSIENT DETECTION, CLASSIFICATION, AND POWER ESTIMATION BASED ON CURRENT WAVEFORM”.

The contents of both above-identified provisional patent applications are hereby incorporated by reference in their entirety.

### TECHNICAL FIELD

This disclosure relates generally to monitoring building energy consumption and, more specifically, to a method and system for providing energy consumption feedback to end users.

### BACKGROUND

Non-intrusive load monitoring (NILM) is a mechanism for providing an energy end user with feedback regarding his or her energy consumption habits based on monitoring the main circuit that feeds electrical power into a house or other location. Generally, the end user is given an energy report that details what appliance(s) in the house or other location consumed what portion(s) of the total electrical energy use. However, currently-available solutions are unsuitable for many appliances, and no complete set of robust and widely accepted appliance features has been identified.

### SUMMARY

Embodiments of this disclosure provide a method and system for monitoring individual appliance energy consumption using non-intrusive load monitoring (NILM).

In a first embodiment, an apparatus for monitoring individual appliance energy consumption using NILM includes an event detection unit configured to detect an ON event and an OFF event within a segment of streaming power input. The event detection unit is configured to extract the streaming power input associated with the ON event in response to detecting the ON event. The extracted streaming power input includes a waveform associated with the ON event recorded over a time frame. The apparatus also includes a signature normalization unit configured to normalize the waveform to reveal one or more unique variations. The apparatus further includes an ON event classification unit configured to classify the normalized waveform based on the one or more unique variations and a rules unit configured to match the ON event with a correlating OFF event based at least on the classification of the normalized waveform. In addition, the apparatus includes a power calculating unit configured to calculate power consumed from a time of the ON event to a time of the OFF event.

In a second embodiment, a method for monitoring individual appliance energy consumption using NILM includes detecting an ON event within a segment of streaming power input and extracting the streaming power input associated with the ON event in response to detecting the ON event. The extracted streaming power input includes a waveform associated with the ON event recorded over a time frame. The method also includes normalizing the waveform to reveal one or more unique variations and classifying the normalized waveform based on the one or more unique variations. The method further includes matching the ON event with a correlating OFF event based at least on the classification of the normalized waveform. In addition, the method includes calculating power consumed from a time of the ON event to a time of the OFF event.

In a third embodiment, an apparatus for monitoring individual appliance energy consumption using NILM includes an event detection unit configured to detect an ON events and an OFF event within a segment of streaming input data. The event detection unit is configured to extract a raw waveform associated with the OFF event in response to detecting the OFF event. The raw waveform includes a first raw waveform of a first period of time before the OFF event and a second raw waveform of a second period of time after the OFF event. The apparatus also includes an alignment unit configured to align the raw waveform with a sinusoid wave using cross-correlation and subtract the second raw waveform from the first raw waveform to produce a third raw waveform of the OFF event. The apparatus further includes a classification unit configured to classify the third raw waveform by subtracting a period of a sine wave from a single period of the third raw waveform. The apparatus also includes a rules unit configured to match the OFF event with a correlating ON event based at least on the classification of the third raw waveform. In addition, the apparatus includes a power calculating unit configured to calculate power consumed from a time of the ON event to a time of the OFF event.

In a fourth embodiment, a method for monitoring individual appliance energy consumption using NILM includes detecting an OFF event within a segment of streaming input data and extracting a raw waveform associated with the OFF event in response to detecting the OFF event. The raw waveform includes a first raw waveform of a first period of time before the OFF event and a second raw wave form of a second period of time after the OFF event. The method also includes aligning the raw waveform with a sinusoid wave using cross-correlation and subtracting the second raw waveform from the first raw waveform to produce a third raw waveform of the OFF event. The method further includes classifying the third raw waveform by subtracting a period of a sine wave from a single period of the third raw waveform. In addition, the method includes matching the OFF event with a correlating ON event based at least on the classification of the third raw waveform and calculating power consumed from a time of the ON event to a time of the OFF event.

Before undertaking the DETAILED DESCRIPTION below, it may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of this disclosure and its advantages, reference is now made to the following description, taken in conjunction with the accompanying drawings, in which:

FIG. 1 illustrates an example embodiment of a non-intrusive load monitoring (NILM) system for monitoring individual appliance energy consumption according to this disclosure;

FIG. 2 illustrates an example embodiment of a NILM apparatus for monitoring individual appliance energy consumption according to this disclosure;

FIG. 3 illustrates example effects of signature normalization according to this disclosure;

FIG. 4 illustrates a first example method for monitoring individual appliance energy consumption using a NILM apparatus according to this disclosure; and

FIG. 5 illustrates a second example method for monitoring individual appliance energy consumption using a NILM apparatus according to this disclosure.

### DETAILED DESCRIPTION

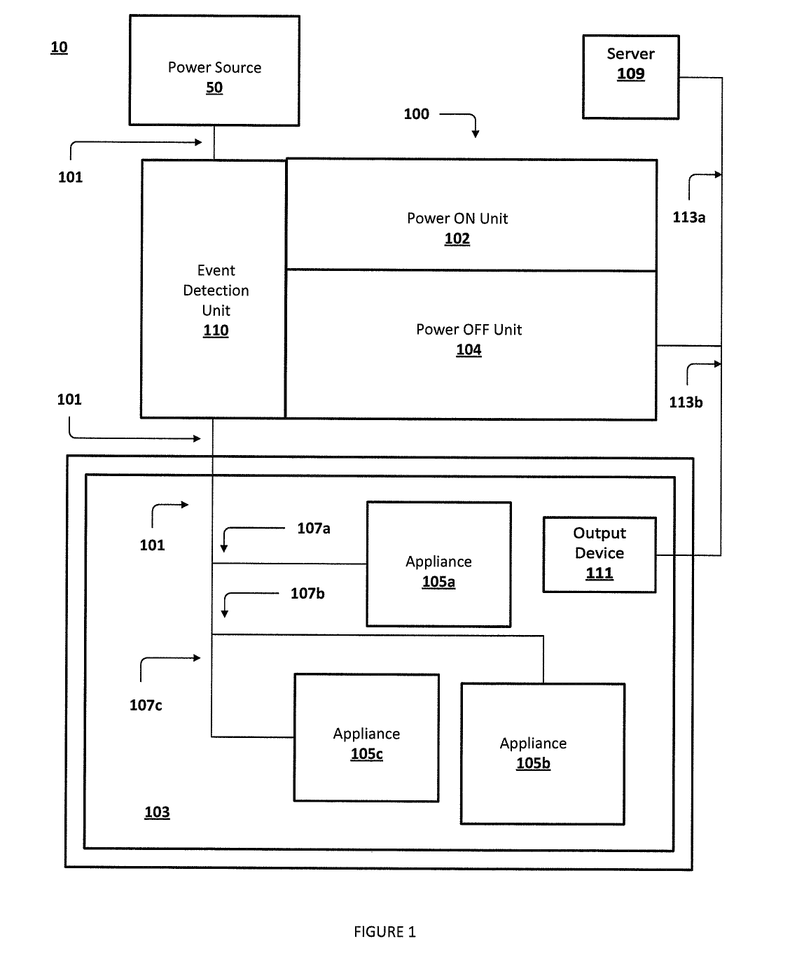

FIGS. 1 through 5, described below, and the various embodiments used to describe the principles of the present invention in this patent document are by way of illustration only and should not be construed in any way to limit the scope of the invention. Those skilled in the art will understand that the principles of the present invention may be implemented in any type of suitably arranged device or system.

Non-intrusive load monitoring (NILM) has been studied for many years as a way of providing energy end users with feedback regarding their energy consumption habits. The overarching idea in this field is to monitor the main circuit that feeds current and voltage into a house, building, or other location and, based on changes in power signatures there, establish an estimate of what appliance (or device) inside the location is turning on and off. Once all appliances with their corresponding states are tracked, an end user is given an energy report that details what appliances consumed what portions of the end user's total energy use. Research has shown that feedback like this can motivate energy savings of up to 20%. This is important because electricity, on its own, currently constitutes 41% of the total annual energy consumption in the United States, and 67% of that is currently produced using fossil fuels. As a result, savings due to NILM-based feedback, in terms of both monetary units and impact on the environment, quickly add up to large amounts when nationwide or even global figures are considered, validating its importance and the need for its adoption.

Recently, unsupervised methods have gained traction, such as those based on graphical models like Bayesian networks and Hidden Markov Models. Electric noise in a voltage line generated by mechanical switches and electromagnetic interference (EMI) noise resulting from switch mode power supplies (SMPS) have also been studied as possible features for device classification. There has been a push towards adding indirect sensors to aid a central NILM system in automating the training and classification of device signatures. Some researchers, for example, have used a combination of several radio-enabled sensors (such as magnetic, acoustic, and light sensors) that send information to a central “fusion center,” which calibrates the sensors automatically and estimates power consumption. Other researchers have tried using Electro Magnetic Field (EMF) event detectors to perform automated training. The available solutions, however, are either unsuitable for some appliances or are still at an early developmental stage, and no complete set of robust and widely accepted appliance features has been identified.

Various challenges of NILM and disadvantages of existing systems and methods include the following.

Low accuracy: Existing systems and methods for monitoring home energy consumption using NILM typically suffer from unsatisfactory disaggregation performance of appliance classification and unsatisfactory power estimation in general whole-home scenarios, including small circuit scenarios where up to three appliances are overlaid. Previous attempts at power estimation have been largely focused on disaggregation at a sub-circuit level and for circuits with up to three appliances. Furthermore, previous attempts reported accuracy of device classification (DC) and power estimation (PE) around only 30% to 50%.

Over-simplified assumptions and testing: Existing systems and methods for monitoring home energy consumption using NILM often focus only on one operational mode of an appliance, even if some appliances have multiple functions exhibiting distinct waveforms. For example, some microwaves have different power level settings, cooking settings (such as popcorn mode and oven mode), and so on. In addition, there are multistate machines such as dish washers that cannot be characterized by one mode but by several distinct on/off modes within a full operational cycle. Such modes may include water heating, drying, rinsing, and washing modes for a dishwasher.

High computational costs: Existing systems and methods for detection and power estimation of multistate appliances are often computationally intensive and difficult to generalize to whole-home circuits. Furthermore, existing systems and methods for detection and power estimation are often difficult to port to a small and low-cost in-house device. Many current systems and methods use Hidden Markov Models (HMMs), which are computationally intensive in the testing/inference phase. Moreover, such methods and systems typically do not yield performance levels high enough to justify this high computational complexity.

Lack of real time report: Many current methods and systems that use HMMs cannot report real-time disaggregation results to end users. This is because such Markov-based time sequence approaches often require long periods of time to observe full operational cycles of whichever appliances are overlaid in order to disaggregate the most likely appliance composition in time. As a result, disaggregation results cannot be reported until after a delay of multiple hours.

The systems and methods disclosed in this patent document address one, some, or all of the above-mentioned disadvantages depending on the implementation. For example, in small-circuit scenarios, the proposed systems and methods could have the following properties.

The proposed systems and methods have a lower computational complexity compared to previous systems and methods based on graphical models.

The proposed systems and methods are scalable to larger environments with more appliances (such as more than three appliances) or with appliances having multiple operational modes.

The proposed systems and methods provide a much higher performance for multi-mode and multi-state appliances than previous systems and methods, yielding much better performance in device classification accuracy for small-circuit scenarios.

Unlike previous systems and methods, the systems and methods disclosed here produce device classification results in real-time (such as about 10 seconds or less) after an actual appliance is turned on. The overall operation of the systems and methods includes at least two phases, including a training phase and a testing phase. The training phase, which labels and segments signal data (such as waveforms) of unique appliances ON state signatures, is presented to a system to be used for learning classification parameters of different modes and different appliances. The signal data collected during the training phase can be stored in a database of the system.

In the testing phase, aggregated continuous streaming data is presented to the system so that the system disaggregates the streaming data in real-time to identify individual appliances. For example, after collecting signal data in the training phase and storing the signals collected in a database of the system, the system can be tested in a simulated environment or a real environment so that the system learns to disaggregate input signals to identify individual appliances. In both the training and testing phases, the streaming data can be real power, reactive power, active power, power harmonics, raw current and voltage, or the like.

It should be understood that while the systems and methods disclosed here are described with respect to small-circuit scenarios, the systems and methods disclosed here are not limited to the size of the circuits nor to the number of modes and appliances to be classified. The systems and method according to the principles of this disclosure can be easily scaled up with little retraining and reasonable increases in computational complexity.

FIG. 1 illustrates an example embodiment of a NILM system 10 for monitoring individual appliance energy consumption according to this disclosure. In this example, the NILM system 10 includes a power source 50, a NILM apparatus 100, and one or more structures 103 (such as one or more houses or buildings). The NILM apparatus 100 may be in electrical communication with a main circuit 101 delivering electrical power from the power source 50 to the one or more structures 103. The one or more structures 103 may contain one or more appliances 105a-105c (such as a dishwasher, a washing machine, a computer, a printer, an air-conditioner, or the like) that consume electrical power via electrical lines 107a-107c in electrical communication with the main circuit 101. The NILM apparatus 100 is configured to estimate the power consumption of each of the one or more appliances 105a-105c by monitoring an power input stream (such as a real power input stream) through the main circuit 101. The NILM system 10 can also include one or more servers 109 and one or more output devices 111. The NILM apparatus 100 can communicate with the one or more servers 109 using wired or wireless communications (such as via electrical lines 113a) and with the one or more output devices 111 using wired or wireless communications (such as via electrical lines 113b). The NILM apparatus 100 can provide output data concerning at least the power consumption of each of the one or more appliances 105a-105c. The one or more servers 109 or the one or more output devices 111 can be configured to provide an energy report that details what appliance(s) in the house or other location consumed what portion(s) of the total energy use. In an embodiment, the energy report can be configured to provide absolute energy consumed in kilowatts or other energy units, total cost, total equivalent CO₂ release or saved, total trees saved, and other representations for each appliance.

In the illustrated embodiment, the NILM apparatus 100 includes a power increase or power ON unit 102 (hereinafter a “power ON unit 102”) and a power decrease or power OFF unit 104 (hereinafter a “power OFF unit 104”). The power ON unit 102 processes signal data related to a power ON event or to an increase in power consumption due to a change in mode of an appliance. The power OFF unit 104 processes signal data related to a power OFF event or to a decrease in power due to a change in mode of an appliance.

The NILM apparatus 100 also includes an event detection unit 110. The event detection unit 110 can be in direct electrical communication with the main circuit 101 and can be coupled to or communicate with the power ON unit 102 and the power OFF unit 104. The event detection unit 110 is configured to identify or detect segments of streaming input data (such as signal data) via the main circuit 101. The streaming input data may include electrical/transient events (hereinafter “electrical events”). Electrical events can include changes in the power input stream (such as changes in electrical energy consumption or electrical energy consumption rates) via the main circuit 101 based on whether a device or appliance is powered on, powered off, or changes state or mode. Generally, an electrical event is a short-lived burst of energy in a system caused by a sudden change of state. An electrical event can generate an electrical signal with an electrical signal signature (such as a waveform of signal data) unique to one or more specific appliances or devices.

In some embodiments, the event detection unit 110 can be configured to identify or detect electrical events that include a change in the streaming power data input beyond a threshold. Also, the event detection unit 110 can be configured to transmit one or more signals to the power ON unit 102 or the power OFF unit 104 when the identified or detected electrical event includes a change in the power input stream beyond a threshold. The one or more signals can include an indication or trigger for the power ON unit 102 or the power OFF unit 104 to begin operation. Furthermore, the signals can include signal data, such as a unique signal signature, related to the electrical event that is recorded over a time frame.

The threshold used by the event detection unit 110 can include a pre-set threshold or a learned threshold. For example, the threshold can be a pre-set threshold so that a change in the real power input stream can be identified or detected by the event detection unit 110 when the change is beyond a pre-set threshold. In some embodiments, a plurality of pre-set thresholds can be used, where each pre-set threshold is designated for a particular time or date.

As another example, the NILM system 10 can be configured to monitor changes in the power input stream for a period of time. By monitoring for the period of time, the NILM apparatus 100 can determine a threshold quantity of change in the power input stream that distinguishes between when a signal should or should not be transmitted to the power ON unit 102 or the power OFF unit 104. In some embodiments, the NILM apparatus 100 may, continuously or at specified intervals, monitor changes in the power input stream for a period of time to adjust the learned threshold accordingly. In other embodiments, the threshold can be determined or adjusted according to training data as discussed above.

When the event detection unit 110 identifies or detects an event (such as the powering on of a washing machine, the powering off of an air-conditioner, a change in mode of a dishwasher, or the like), the event detection unit 110 transmits one or more signals to at least one of the power ON unit 102 and the power OFF unit 104. The one or more signals indicate that an event has taken place. The receipt of the one or more signals by the power ON unit 102 or the power OFF unit 104 can trigger the operation of each unit, respectively.

It should be noted that the computational complexity of the NILM apparatus 100 can be largely reduced because the event detection unit 110 transmits one or more signals in response to identifying or detecting an electrical event. Thus, the operation of the power ON unit 102 or the power OFF unit 104 may be triggered in response to the event detection unit 110 identifying or detecting an electrical event. This may occur instead of, for example, triggering the operation of the power ON unit 102 or the power OFF unit 104 at each shifting time window.

In operation, the event detection unit 110 identifies or detects sample points of an input data stream associated with the main circuit 101. The event detection unit 110 checks the difference between each individual sample point (such as the magnitude of the power input stream) and each preceding individual sample point. Upon identifying or detecting a difference that exceeds a threshold, the event detection unit 110 can monitor the magnitude of the power input stream (such as the real power input stream) for a time frame (such as 100 milliseconds). During this time, the event detection unit 110 identifies or detects if the change in the magnitude of the power input stream is maintained at least at an average amount or percentage (such as 70%) of the initial change to the magnitude of the power input stream. If the change over the time frame is maintained, the event detection unit 110 may record the signal data (such as a waveform) related to the electrical event over the time frame. Because event detection is based on relatively small amounts of data, event detection can often produce real-time results within a short period of time, such as within 1 to 10 seconds depending on the computation processor.

The event detection unit 110 may also identify or detect that an ON event, an OFF event, or a change in state or mode of a device requiring more or less energy has occurred. The event detection unit 110 may then extract a segment of the streaming input power related to the electrical event, which was recorded over the time frame, and transmit data associated with the streaming input power to at least one of the power ON unit 102 and the power OFF unit 104 for further processing. For example, the event detection unit 110 may identify or detect that an ON event has occurred, extract a segment of the streaming input power related to the ON event, and transmit the segment of the streaming input power to the power ON unit 102.

Although FIG. 1 illustrates one example embodiment of a NILM system 10 for monitoring individual appliance energy consumption, various changes may be made to FIG. 1. For example, a NILM system could include any number of NILM apparatuses 100 monitoring energy usage in any number of structures 103. Also, a NILM apparatus 100 could monitor energy usage by any number of appliances.

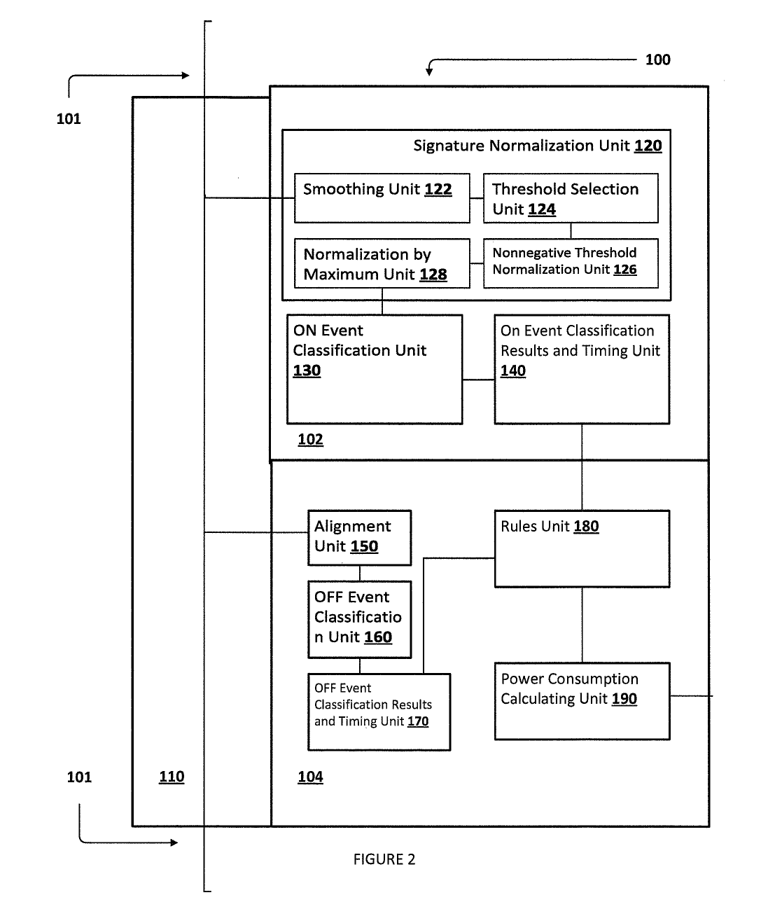

FIG. 2 illustrates an example embodiment of a NILM apparatus 100 for monitoring individual appliance energy consumption according to this disclosure. As illustrated in FIG. 2, the power ON unit 102 includes a signature normalization unit 120, an ON event classification unit 130, and an ON event classification results and timing unit 140. The signature normalization unit 120 is a mapping unit where unique signal signatures from segments of streaming input power are more easily distinguished from each other. This allows the NILM apparatus 100 to better distinguish between appliances or devices consuming energy via the main circuit 101. The signature normalization unit 120 may communicate with the event detection unit 110 and the ON event classification unit 130. The signature normalization unit 120 may begin operation when receiving one or more segments of streaming input power from the event detection unit 110 as previously described.

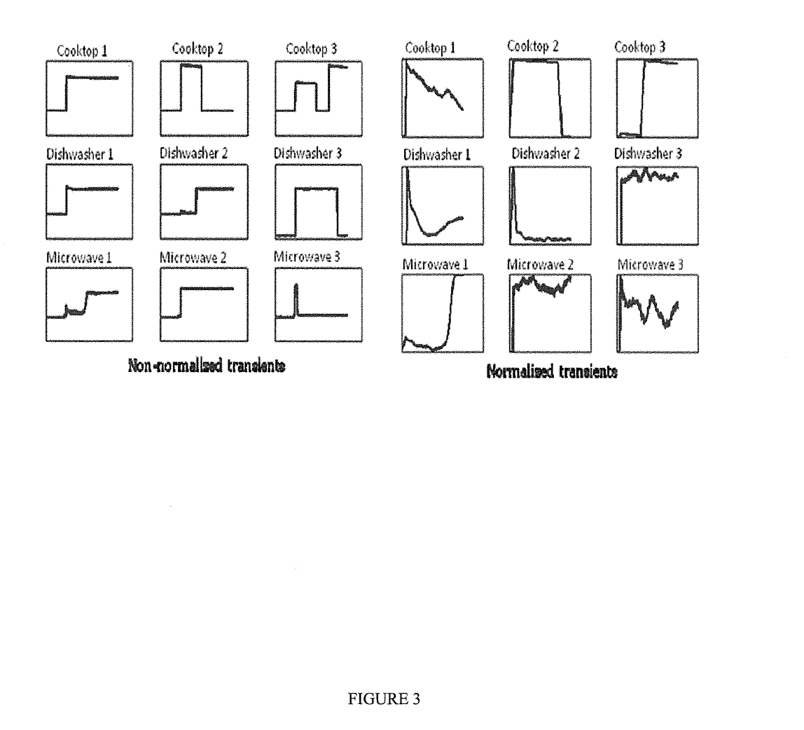

Generally, when most appliances are powered on, their signal signatures (such as electrical waveforms) at a relatively broad vantage point include a large common (roughly rectangular) shape. However, through the signature normalization unit 120 performing signature normalization, a signal signature of a first appliance can be distinguished from a signal signature of a second or different appliance by enhancing the large common shapes of the signal signatures to reveal unique variations and thus unique signal signatures. The signature normalization unit 120 is therefore configured to normalize the signal signatures of ON events to reveal unique variations in signal signatures. By distinguishing between unique signal signatures, the power consumption of a particular appliance can be identified and calculated or estimated by monitoring energy consumption through the main circuit 101. FIG. 3 illustrates example effects of signature normalization according to this disclosure. Furthermore, for high frequency components, normalization can be accomplished with a high-pass filter or band-pass filter, which can focus on specific frequency ranges.

In this example, the signature normalization unit 120 includes a smoothing unit 122, a threshold selection unit 124, a nonnegative threshold normalization unit 126, and a normalization by maximum unit 128. The smoothing unit 122 receives segments of streaming power input data including a signal signature recorded over a time frame by the event detection unit 110. The smoothing unit 122 smoothes the signal signature and generates a signal signature representing an average energy consumption over the time frame. In some embodiments, the average energy consumption over the time frame can be implemented by convolution with a time length (such as 5 milliseconds) all ones vector. Time length portions at the beginning and at the end of the resulting smooth signal can then be removed, as these portions may contain mostly artifacts or by-products from the smoothing. Note, however, that other filtering techniques or noise-reducing/eliminating techniques can also be applied.

The threshold selection unit 124 sorts the root mean square (RMS) of the real power values for each resulting smooth signal signature. Generally, the power value at the lowest percentage level (such as 1%, 5%, 10%, 15%, 20%, or the like) is selected as a power level threshold. In some embodiments, instead of or in addition to RMS of real power, the received signal signature can be at least one of: reactive power, current RMS, harmonics, coefficients, or representations based on other signal decompositions.

The nonnegative threshold normalization unit 126 normalizes the smoothed signal signature by performing a point wise minus of the power level threshold and converting any resulting value to zero. The normalization by maximum unit 128 further normalizes the signal signature by dividing the maxima RMS value of the smoothed signal signature (such as max-based normalization) generated by the nonnegative threshold normalization unit 126. However, other normalization processes could be supported, such as by normalizing a percentage from the top percentage or energy-based normalization.

The ON event classification unit 130 in the power ON unit 102 classifies normalized signal signatures produced or generated by the signature normalization unit 120. The ON event classification unit 130 can use normalized signal signature classification information gathered during the training and testing phases previously discussed. The ON event classification unit 130 compares received normalized signal signatures from the signature normalization unit 120 with signal signatures of appliances/devices or modes of appliances/device gathered during the training and testing phases to determine or identify which appliance or mode thereof generated the received normalized signal signature. The appliance or mode of the appliance may be determined by selecting the signal signature stored during the training and testing phases that has the smallest distances from the normalized signal signature identified by the signature normalization unit 120.

In some embodiments, the ON event classification unit 130 uses a classification technique implementing a basic k-nearest neighbor (kNN) search between a normalized signal signature and acquired training data to associate or classify the normalized signal signature with a particular appliance or a particular mode of an appliance. However, the ON event classification unit 130 could use other classification techniques, such as discriminant analysis (LDA), support vector machines (SVM), and neural networks (NN). Classification techniques may involve calculating Euclidean distances between vectors (such as vectors 100 millisecond long) representing the normalized signal signature and the signal signatures stored during the training and testing phases. The NILM apparatus 100 can classify quantities of data such as data related to a single appliance (a small amount of data) or data related to a plurality of appliances (very large amounts of data) to produce real-time results at significant levels of performance.

Moreover, in some embodiments, when the ON event classification unit 130 detects one operational mode of an appliance, the ON event classification unit 130 can use known associations or sequences of the appliance's operational modes to detect other events associated with the appliance. For example, the ON event classification unit 130 can check or compare signal signatures stored in the ON event classification unit 130 with a received signal signature to determine if a dishwasher ON mode or other mode has previously occurred. If another dishwasher mode has been classified before within an operational cycle interval, the ON event classification unit 130 can classify the signal signature as a heating mode. If none of the other dishwasher modes have been identified, the ON event classification unit 130 can classify the signal signature as the next closest training signal signature neighbor.

The ON event classification unit 130 can be equipped with appliance-specific information other than normalized signal signatures obtained during training and testing phases. Examples of commonly-used appliance-specific information includes the power level of steady state operation and state transition information. For example, power thresholding provided by the ON classification unit 130 can be used among appliances and modes whose RMS powers differ by a specified amount (such as 5%, 10%, 20%, or more) such that a level of power change due to circuit nonlinearity is expected. For example, power thresholding can be used to distinguish a cooktop from a dishwasher by examining the step change in terms of RMS power and comparing the step change with information gathered during the training and testing phases to see if it is lower than a threshold. State transition information provided by the ON event classification unit 130 can be used in the case of a dishwasher in a heating mode, for example, whose data signal signature is a pure resistive circuit signature similar to a number of other appliances, such as cooktop and other heating appliances.

Once a normalized signal signature is classified by the ON event classification unit 130, the ON event classification unit 130 can transfer the classified signal signature to the ON event classification result and timing unit 140. The unit 140 can keep track of previously identified states. For example, the unit 140 can keep track of one or more ON events associated with one or more specific appliances/devices or changes in modes of one or more appliances/devices. The unit 140 is in communication with a rules unit 180, which is described below.

Note that event detection is described here as involving subtraction and comparison, and signature normalization is described here as involving convolution, sorting, subtraction, and comparison. Also, device classification is described here as involving computation of Euclidean distances and maximums. All of these operations are of complexity up to O(n log n)+O(kn), where n is the sample size (such as about 200 per event) and k is the number of appliances and modes (typically around ten in small circuits). Thus, the computational complexity is low. Furthermore, by using a kNN scaling method for device classification (where scaling up only requires adding new normalized training samples), device classification can be scaled up to accommodate new appliances easily. Conversely, other classifying methods like LDA, SVM, and neural networks often require retraining of the classifier or adding (such as manually) new classifiers into the system.

In small-circuit tests that involved many of the most frequently-used kitchen appliances (microwave, cooktop, and dishwasher) having a total of 10 operational modes/states, one example implementation of the system 10 can achieve an accuracy in device classification over 95% and an accuracy in power estimation of over 80% (power estimation with proper OFF detection) at a per-event level. Of course, other implementations of the system 10 could obtain different results, depending on the training sequences and other factors. Thus, the system 10 largely improves upon conventional appliance classification and power estimation accuracy with respect to NILM technology. This is highly desirable since NILM technology is a central element of smart home and home energy optimization technologies and has a huge global market.

Continuing with FIG. 2, the event detection unit 110 can also identify or detect that an OFF event has occurred. In response, the event detection unit 110 extracts and stores the raw current waveforms for a first period of time (such as 200 milliseconds) before the OFF event occurs and for a second period of time (such as 200 milliseconds) after the OFF event occurs. The raw current waveforms can be sent to the power OFF unit 104. As illustrated in FIG. 2, the power OFF unit 104 generally includes an alignment unit 150, an OFF event classification unit 160, an OFF event classification results and timing unit 170, a rules unit 180, and a power consumption calculating unit 190.

The alignment unit 150 communicates with the event detection unit 110 and the OFF event classification unit 160. The alignment unit 150 is configured to align the received raw current waveforms recorded from the first time period before the OFF event, through the OFF event, and until the end of the second time period after the OFF event with a sinusoidal waveform. The alignment can occur, for example, based on a cross correlation with a 60 Hz sinusoidal wave. The sinusoidal waveform can include a wave similar to the length of the received raw current waveforms (such as 200 milliseconds). After the raw current waveforms are aligned with the sinusoidal wave, a portion of the raw current waveform from the first time period before the OFF event is subtracted from a portion of the raw current waveform from the second time period after the OFF event. By doing so, the waveform at the time of the OFF event can be produced. The alignment unit 150 is configured to transmit the waveform at the time of the OFF event to the OFF event classification unit 160. The alignment of the raw current waveforms can also be done in other ways, such as by using a raw voltage signal as a reference signal.

The OFF event classification unit 160 subtracts a period of a sine wave (such as a 60 Hz or 120 Hz sine wave) from a single period of the waveform received from the alignment unit 150 to determine if the received waveform is above a threshold. The OFF event classification unit 160 can also check the maximum value of the difference between the received waveform and the sine wave to determine if the waveform is above a threshold. If the received waveform is above a threshold, the OFF event classification unit 160 can classify the waveform to be within a group of devices with non-resistive components, such as a microwave. If the received waveform is below a threshold, the OFF event classification unit 160 can classify the waveform to be within a group of pure resistive devices. In some embodiments, kNN classification can be used to determine the exact device identity of the appliance that was turned off.

Once the OFF event classification unit 160 classifies the received waveform, the OFF event classification unit 160 transmits the classified waveform to the OFF event classification results and timing unit 170. The unit 170 can keep track of previously-identified states. For example, the unit 170 can keep track of one or more OFF events associated with one or more specific appliances/devices or changes in modes of one or more specific appliances/devices. The unit 170 is in communication with the rules unit 180.

The rules unit 180 is in communication with the ON event classification results and timing unit 140 and the OFF event classification results and timing unit 170. The ON event classification results and timing unit 140 transmits ON events to the rules unit 180, and the OFF event classification result and timing unit 170 transmits OFF events to the rules unit 180. The rules unit 180 is configured to keep count of the number of particular appliances/devices that are ON at any given time by checking the difference between the number of detected ON events and the number of detected OFF events at any given period of time. The rules unit 180 is also configured to match an ON event with a correlating OFF event based at least on the classification of the normalized waveform of the ON event or the classification of the raw waveform of the OFF event in order to close an appliance operation cycle.

For example, if a particular appliance is in an ON state and if the same appliance's OFF raw current waveform has been detected, the rules unit 180 can match the particular appliance ON signal signature with the same particular appliance's OFF raw current waveform and classify the ON signal signature and the OFF raw current waveform of the appliance as an ON/OFF cycle, closing the operational cycle of the appliance. In some embodiments, the rules unit 180 can be configured to match an ON signal signature with an OFF raw current waveform and classify an ON/OFF cycle if the power difference between a step change when an appliance was OFF and when the appliance was ON is less than a specified amount (such as 20%) of a minimum of the ON and OFF power.

In some instances, the rules unit 180 may not detect or match an OFF event corresponding to a detected ON event for a particular appliance (or vice versa). In this case, the rules unit 180 is configured to drop or discard the non-correlated or unmatched ON or OFF event without forcing a closing of an operational cycle. By dropping or discarding non-correlated events, the rules unit 180 prevents matching errors from propagating and producing power estimates based on incorrectly correlated events.

Once an ON/OFF cycle is detected by the rules unit 180, the rules unit 180 transmits data associated with the correlated ON and OFF events to the power consumption calculating unit 190. Data associated with the ON event can include a time when the ON event occurred. Based on the waveforms associated with the correlated ON and OFF events, the power consumption calculating unit 190 is configured to calculate the estimated power consumed by the operational cycle of the appliance. Calculating the estimated power can include multiplying the power consumption when the appliance is powered OFF with the duration between the ON and OFF events. In instances of overlapping events, the power consumption calculating unit 190 is configured to use a step change as a proxy to estimate the power consumption of the devices during the overlapping period.

The power consumption calculating unit 190 can also be configured to check the accuracy of the power consumption estimation. For example, the power consumption calculating unit 190 can be configured to sum up power consumption estimations of the appliances/devices that have been classified by the ON event classification unit 130, the OFF event classification unit 170, or matched by the rules unit 180. The power consumption calculating unit 190 is configured to check the difference of the sum with total power consumption in a structure. In some embodiments, the total power consumption can be transmitted from the event detection unit 110 to the rules unit 190.

Note that the length of raw current waveforms before and after an OFF event can vary. Longer waveforms can be associated with better signal-to-noise ratios, but computational complexity and delay increase as waveforms increase in length. Furthermore, with appliances/devices having fast changes in power level or raw current waveforms, longer waveforms can result in additional complexity and variation, which can complicate the classification process.

The power consumption calculating unit 190 can also be configured to transmit the power consumption estimations to an output device 111 or server 109. In some embodiments, once the power consumption calculating unit 190 calculates the power consumption estimations, the power consumption estimations are transmitted to the server 109, where the power consumption estimations can be accessed by a user via a webpage or through a power service provider. In other embodiments, the power consumption estimations are transmitted directly to an output device 111 (such as a mobile telephone), which can be accessed by a user directly.

Although FIG. 2 illustrates one example embodiment of a NILM apparatus 100 for monitoring individual appliance energy consumption, various changes may be made to FIG. 2. For example, the functional division shown in FIG. 2 is for illustration only. Various components in FIG. 2 could be combined, further subdivided, or omitted and additional components could be added according to particular needs. Also, each unit in the NILM apparatus 100 could be implemented using hardware or a combination of hardware and software/firmware instructions. If software/firmware instructions are used, the software/firmware instructions of each unit could be executed on a separate processing device, or the software/firmware instructions of multiple units could be executed by one or more common processing devices. Although FIG. 3 illustrates examples of effects of signature normalization, various changes may be made to FIG. 3. For instance, the signature normalizations shown in FIG. 3 are examples only and do not limit the scope of this disclosure.

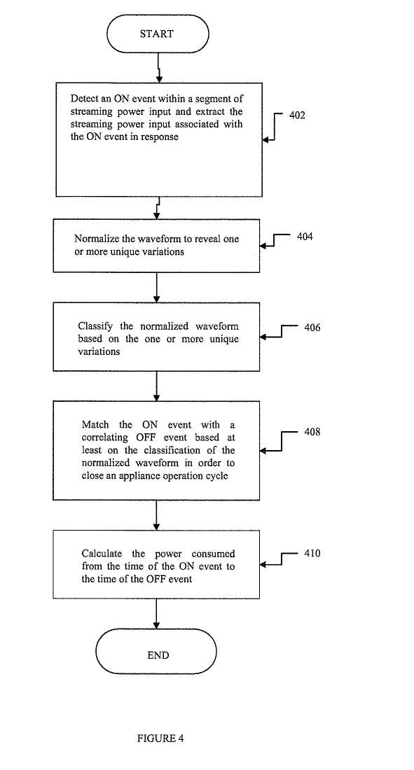

FIG. 4 illustrates a first example method 400 for monitoring individual appliance energy consumption using a NILM apparatus according to this disclosure. For ease of explanation, the method 400 is described with respect to the NILM apparatus 100 of FIG. 2. However, the method 400 could be used with any other suitable NILM apparatus.

The event detection unit 101 detects an ON event within a segment of streaming power input and extracts the streaming power input associated with the ON event in response at step 402. The streaming power input includes a waveform associated with the ON event recorded over a time frame.

The signature normalization unit 120 normalizes the waveform to reveal one or more unique variations at step 404. Normalizing the waveform can include smoothing the waveform, sorting the RMS of power values of the smoothed waveform, implementing a point wise minus a power level threshold, and dividing the maxima RMS value of the smoothed waveform.

The ON Event classification unit 130 classifies the normalized waveform based on the one or more unique variations at step 406. Classifying the normalized waveform can include using a kNN search between the normalized waveform and acquired training data to associate the normalized waveform with a particular appliance or a mode of a particular appliance.

The rules unit 180 matches the ON event with a correlating OFF event based at least on the classification of the normalized waveform in order to close an appliance operation cycle at step 408. If no match for an ON event is found, the rules unit 180 could discard the ON event without forcing a closing of an operation cycle.

The power consumption calculating unit 190 calculates the power consumed from a time of the ON event to a time of the OFF event at step 410. Calculating the power consumed can include multiplying the power consumption at the time of the OFF event by the duration between the time of the ON event and the time of the OFF event.

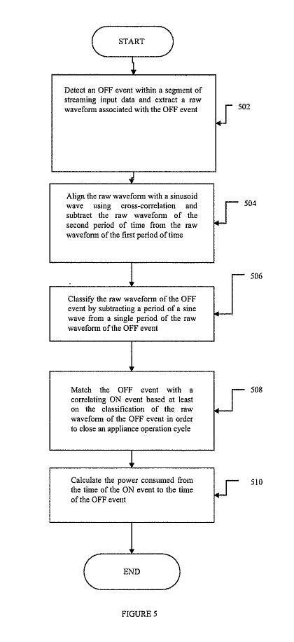

FIG. 5 illustrates a second example method 500 for monitoring individual appliance energy consumption using a NILM apparatus according to this disclosure. For ease of explanation, the method 500 is described with respect to the NILM apparatus 100 of FIG. 2. However, the method 500 could be used with any other suitable NILM apparatus.

As shown in FIG. 5, the event detection unit 101 detects an OFF event within a segment of streaming input data and extracts a raw waveform associated with the OFF event in response at step 502. The raw waveform includes a raw waveform of a first period of time before the OFF event and a raw wave form of a second period of time after the OFF event.

The aligning unit 150 aligns the raw waveform with a sinusoid wave using cross-correlation and subtracts the raw waveform of the second period of time from the raw waveform of the first period of time at step 504. This produces a raw waveform of the OFF event.

The OFF event classification unit 160 classifies the raw waveform of the OFF event by subtracting a period of a sine wave from a single period of the raw waveform of the OFF event at step 506. Classifying the raw waveform can also include identifying the maximum value of the difference between the period of the sine wave and the single period of the raw waveform and comparing the maximum value with a threshold. Classifying the raw waveform can further include using a kNN search between the normalized waveform and acquired training data to associate the normalized waveform with a particular appliance or a mode of a particular appliance.

The rules unit 180 matches the OFF event with a correlating ON event based at least on the classification of the raw waveform of the OFF event in order to close an appliance operation cycle at step 508. If no match for the OFF event is found, the rules unit 180 can discard the OFF event without forcing a closing of an operation cycle.

The power consumption calculating unit 190 calculates the power consumed from the time of the ON event to the time of the OFF event at step 510. Calculating the power consumed can include multiplying the power consumption at the time of the OFF event by the duration between the time of the ON event and the time of the OFF event.

Although FIGS. 4 and 5 illustrate examples of methods for monitoring individual appliance energy consumption using a NILM apparatus, various changes may be made to FIGS. 4 and 5. For example, while shown as a series of steps, various steps in each figure could overlap, occur in parallel, or occur multiple times.

In some embodiments, various functions described above (such as functions of the NILM apparatus 100) are implemented or supported by one or more computer programs, each of which is formed from computer readable program code and embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus for monitoring individual appliance energy consumption using non-intrusive load monitoring (NILM), the apparatus comprising:
an event detection unit configured to detect an ON event and an OFF event within a segment of streaming power input, the event detection unit configured to extract the streaming power input associated with the ON event in response to detecting the ON event, the extracted streaming power input comprising a waveform associated with the ON event recorded over a time frame;
a signature normalization unit configured to normalize the waveform to reveal one or more unique variations;
an ON event classification unit configured to classify the normalized waveform based on the one or more unique variations;
a rules unit configured to match the ON event with a correlating OFF event based at least on the classification of the normalized waveform; and
a power calculating unit configured to calculate power consumed from a time of the ON event to a time of the OFF event.

2. The apparatus of claim 1, wherein the event detection unit is configured to monitor a magnitude of the streaming power input over the time frame and determine if the magnitude of the streaming power input is maintained at or above a specified level.

3. The apparatus of claim 1, wherein the signature normalization unit is configured to normalize the waveform by smoothing the waveform, sorting a root mean square (RMS) of power values of the smoothed waveform, implementing a point wise minus a power level threshold, and dividing a maxima RMS value of the smoothed waveform.

4. The apparatus of claim 1, wherein the ON event classification unit is configured to classify the normalized waveform using a k-nearest neighbor (kNN) search between the normalized waveform and acquired training data to associate the normalized waveform with a particular appliance or an operational mode of a particular appliance.

5. The apparatus of claim 4, wherein the training data comprises waveforms previously identified by the apparatus.

6. The apparatus of claim 1, wherein the power calculating unit is configured to calculate the power consumed by multiplying power consumption at the time of the OFF event by a duration between the time of the ON event and the time of the OFF event.

7. A method for monitoring individual appliance energy consumption using non-intrusive load monitoring (NILM), the method comprising:
detecting an ON event and an OFF event within a segment of streaming power input and extracting the streaming power input associated with the ON event in response to detecting the ON event, the extracted streaming power input comprising a waveform associated with the ON event recorded over a time frame;
normalizing the waveform to reveal one or more unique variations;
classifying the normalized waveform based on the one or more unique variations;
matching the ON event with a correlating OFF event based at least on the classification of the normalized waveform; and
calculating power consumed from a time of the ON event to a time of the OFF event.

8. The method of claim 7, further comprising:
monitoring a magnitude of the streaming power input over the time frame; and
determining if the magnitude of the streaming power input is maintained at or above a specified level.

9. The method of claim 7, wherein normalizing the waveform comprises smoothing the waveform, sorting a root mean square (RMS) of power values of the smoothed waveform, implementing a point wise minus a power level threshold, and dividing a maxima RMS value of the smoothed waveform.

10. The method of claim 7, wherein classifying the normalized waveform comprising using a k-nearest neighbor (kNN) search between the normalized waveform and acquired training data to associate the normalized waveform with a particular appliance or an operational mode of a particular appliance.

11. The method of claim 10, wherein the acquired training data comprises previously classified waveforms.

12. The method of claim 7, wherein calculating the power consumed comprises multiplying a power consumption at the time of the OFF event by a duration between the time of the ON event and the time of the OFF event.

13. An apparatus for monitoring individual appliance energy consumption using non-intrusive load monitoring (NILM), the apparatus comprising:
an event detection unit configured to detect an ON event and an OFF event within a segment of streaming input data, the event detection unit configured to extract a raw waveform associated with the OFF event in response to detecting the OFF event, the raw waveform comprising a first raw waveform of a first period of time before the OFF event and a second raw wave form of a second period of time after the OFF event;
an alignment unit configured to align the raw waveform with a sinusoid wave using cross-correlation and subtract the second raw waveform from the first raw waveform to produce a third raw waveform of the OFF event;
a classification unit configured to classify the third raw waveform by subtracting a period of a sine wave from a single period of the third raw waveform;
a rules unit configured to match the OFF event with a correlating ON event based at least on the classification of the third raw waveform; and
a power calculating unit configured to calculate the power consumed from the time of the ON event to the time of the OFF event.

14. The apparatus of claim 13, wherein the classification unit is configured to identify a maximum value of a difference between the period of the sine wave and the single period of the third raw waveform and compare the maximum value with a threshold.

15. The apparatus of claim 13, wherein the classification unit is configured to classify the third raw waveform using a k-nearest neighbor (kNN) search between the third raw waveform and acquired training data to associate the third raw waveform with a particular appliance or an operational mode of a particular appliance.

16. The apparatus of claim 15, wherein the training data comprises waveforms previously identified by the apparatus.

17. The apparatus of claim 13, wherein the rules unit is configured to discard any unmatched ON and OFF events.

18. A method for monitoring individual appliance energy consumption using non-intrusive load monitoring (NILM), the method comprising:
detecting an ON event and an OFF event within a segment of streaming input data and extracting a raw waveform associated with the OFF event in response to detecting the OFF event, the raw waveform comprising a first raw waveform of a first period of time before the OFF event and a second raw wave form of a second period of time after the OFF event;
aligning the raw waveform with a sinusoid wave using cross-correlation and subtracting the second raw waveform from the first raw waveform to produce a third raw waveform of the OFF event;
classifying the third raw waveform by subtracting a period of a sine wave from a single period of the third raw waveform;
matching the OFF event with a correlating ON event based at least on the classification of the third raw waveform; and
calculating the power consumed from the time of the ON event to the time of the OFF event.

19. The method of claim 20, wherein classifying the third raw waveform comprises identifying a maximum value of a difference between the period of the sine wave and the single period of the raw waveform and comparing the maximum value with a threshold.

20. The method of claim 18, wherein classifying the third raw waveform comprises using a k-nearest neighbor (INN) search between the third raw waveform and acquired training data to associate the third raw waveform with a particular appliance or an operational mode of a particular appliance.

21. The method of claim 20, wherein the acquired training data comprises previously classified waveforms.

22. The method of claim 18, further comprising:
discarding any unmatched ON and OFF events.
